(19) United States
(12) Patent Application Publication
(10) Pub. No.: US 2007/0091961 A1
(43) Pub. Date: Apr. 26, 2007

(54) Method and structure for low stress oxide VCSEL

(76) Inventors: Chao-Kun Lin, Fremont, CA (US); Scott W. Corzine, Sunnyvale, CA (US); Michael R. T. Tan, Menlo Park, CA (US)

Correspondence Address: AVAGO TECHNOLOGIES, LTD., P.O. BOX 1920, DENVER, CO, 80201-1920, US

(21) Appl. No.: 11/246,739

(22) Filed: Oct. 7, 2005

(51) Int. Cl. H01S 5/00

(52) U.S. Cl. 372/50.124

(57) ABSTRACT

The etched sidewalls of laterally oxidized VCSEL structures are coated with a dielectric film to inhibit oxidation of the DBR layers during the oxidation process. While oxidation of the DBR mirror layers is not completely eliminated, the number of DBR mirror layers that are oxidized is significantly reduced, thereby reducing the DBR oxide stress.

### BACKGROUND

AlGaAs oxide vertical cavity surface emitting lasers (VCSELs) at 850 nm are widely used for low-cost optical fiber transceivers because of their low threshold current, high efficiency and high modulation speeds. A typical AlGaAs VCSEL structure has a λ/n thick active region with embedded quantum wells, two distributed Bragg reflectors (DBRs) sandwiching the active region. λ is the operating wavelength and n is the refractive index. The DBRs are formed of stacks of multiple periods of alternating λ/4n thick low and high refractive index layers to provide high reflectivity for the light. DBR pairs used in 850 nm VCSELs are typically AlₓGa₁₋ₓAs/Al_{y}Ga_{1-y}As where x is typically about 0.2 and y is typically between 0.86 and about 0.9.

The oxide apertures of AlGaAs VCSELs are formed by wet oxidation. One or more current confinement layers with a higher Al composition are positioned in the DBR stacks and subsequently oxidized at temperatures in excess of 400° C. in a water vapor ambient to create the current aperture. As described in U.S. Pat. No. 5,896,408 and incorporated by reference, the oxidation rate is a strong function of the Al composition so that the rate of the oxidation in the current confinement layers is typically much greater than the oxidation rate in the DBR layers.

Experimentally, the linear thickness shrinkage of the oxidized AlGaAs layers is measured to be between about 7 percent to about 12 percent depending on the precise Al composition. The volume shrinkage of the oxidized AlGaAs layer near the active region creates compressive stress that creates reliability problems. Significant effort has been expended to minimize the stress for surrounding layers.

However, dark line defects (DLDs) originating from the oxide and semiconductor interface near the edge of the DBRs extend inward into the current aperture and produce dark areas in the active region when the VCSEL operates. These DLDs are generated by oxide shrinkage in the DBR mirror layer at the mesa edge. The DBR oxide stress shown in FIG. 1 typically cannot be reduced by changing the grading layer design or shaping the oxide terminus because of the thickness requirement for the DBRs.

### SUMMARY OF THE INVENTION

In accordance with the invention, the etched sidewalls of laterally oxidized VCSEL structures are coated with a conformal dielectric film to inhibit oxidation of the DBR layers during the oxidation process. While oxidation of the DBR mirror layers is typically not completely eliminated, the number of DBR mirror layers that are oxidized is typically significantly reduced, thereby reducing the DBR oxide stress.

### BRIEF DESCRIPTION OF THE DRAWINGS

FIG. 1 is an SEM cross-section showing the extent of the oxidation into the DBR mirror layers in the prior art.

FIG. 2a-d shows the steps for making an embodiment in accordance with the invention.

FIG. 3 is an SEM cross-section showing the extent of the oxidation into the DBR mirror layers for an embodiment in accordance with the invention.

### DETAILED DESCRIPTION

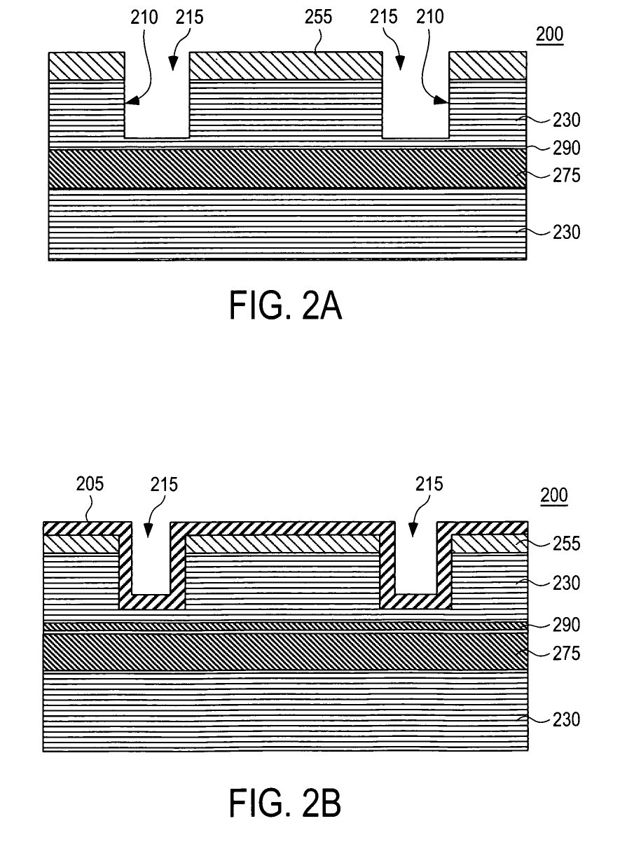

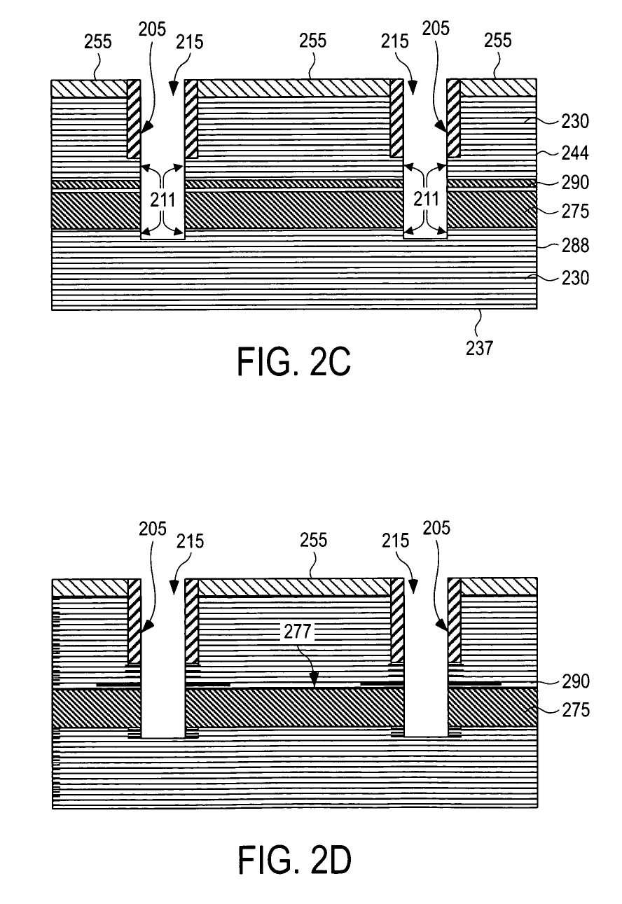

FIGS. 2a-d show the modifications to the standard oxide VCSEL process (for example, see U.S. Pat. No. 5,896,408 or U.S. Pat. No. 5,978,408 incorporated herein by reference) to coat etched sidewalls 210 of oxide VCSEL structure 200 with conformal dielectric film 205 (see FIG. 2b) to inhibit DBR layers 230 typically supported on substrate 237 from oxidizing during the current aperture oxidation process in accordance with the invention. In the standard oxide VCSEL process, oxide VCSEL structure 200 in FIG. 2a is exposed to water vapor in an oxidation furnace at greater than about 400° C. Further details regarding the oxidation process may be found in K. D. Choquette et al, Electronics Letters 30, p. 2043, 1994 incorporated herein by reference. In particular, Choquette et al. show the strong dependence of the oxidation rate on the aluminum content in a layer, especially for an aluminum content of over about 90 percent.

FIG. 2a shows oxidation cavities 215 that are formed by a dry etching process in a plasma etcher such as, for example, reactive ion etching (RIE) system, inductively coupled plasma (ICP)-RIE or electron cyclotron resonance (ECR)-RIE using dielectric mask 255. Oxidation cavities 215 may typically be trenches, holes or similar structures. Instead of dry etching through current confinement layer 290 and active layer 275 having an active region, the dry etch is typically stopped above current confinement layer 290. For example, an end-point system can be used to count the number of DBR pairs of DBRs 230 and determine when the dry etch is to be stopped, typically within±1 DBR mirror layer. The end-point system uses laser interferometry. Alternatively, a hard etch stop may be used, for example, by replacing the AlGaAs material of high refractive index layer 244 with an InGaP or an InGaAsP containing material; or the AlGaAs material of the corresponding low refractive index layer may be replaced with the appropriate index matched material.

Then, as shown in FIG. 2b, oxide VCSEL structure 200 is typically placed in a deposition chamber. Conformal dielectric film 205 having a thickness typically in the range from about 750 Å to about 1000 Å is deposited over dielectric mask 235 and sidewalls 210 of DBRs 230 typically using plasma enhanced chemical vapor deposition (PECVD) or sputtering deposition. Conformal dielectric film 205 may be, for example, Si₃N₄, SiC or SiO₂ or other conformal dielectric film that tolerates temperatures greater than about 400° C. Following deposition of conformal dielectric film 205, oxide VCSEL structure 200 is transferred back to the dry etcher for additional etching.

Because dry etching is typically anisotropic, conformal dielectric film 205 on the bottom of cavity 215 in FIG. 2b is eroded by ion bombardment and the etching of DBR layers 230, current confinement layer 290 and active layer 275 is continued to the desired depth as shown in FIG. 2c but conformal dielectric film 205 on sidewalls 210 is typically not eroded. Again an end-point system may be used be used to count the DBR pairs of DBRs 230 and determine when the dry etch is to be stopped within ±1 DBR mirror layer. Alternatively, a hard etch stop may be used, for example, by replacing the AlGaAs material of high refractive index layer 288 with an InGaP or an InGaAs material or the AlGaAs material of the corresponding low refractive index layer may be replaced with the appropriate index matched material.

The portion of conformal dielectric film 205 on sidewalls 210 does not receive ion bombardment and the typical AlGaAs etching chemistry does not chemically attack conformal dielectric film 205. The result is that most of sidewalls 210 are protected by conformal dielectric film 205 and only small portions 211 (see FIG. 2c) of sidewalls 210 of DBRs 230 are exposed to the environment. Oxide VCSEL structure 200 is then placed into an oxidation furnace and exposed to temperatures greater than about 400° C. for oxidation, typically using water vapor to provide oxidation.

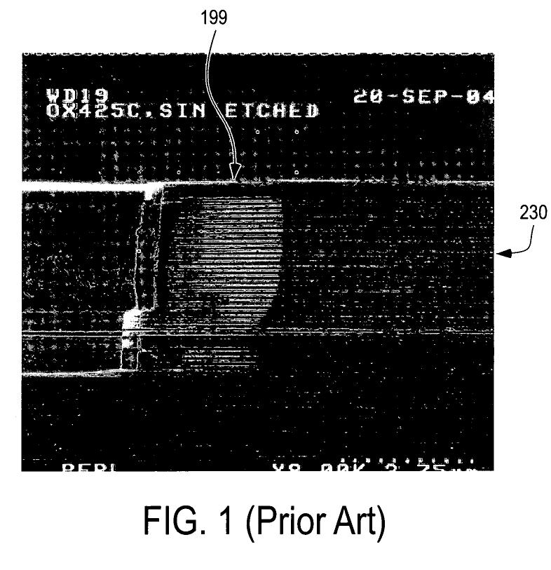

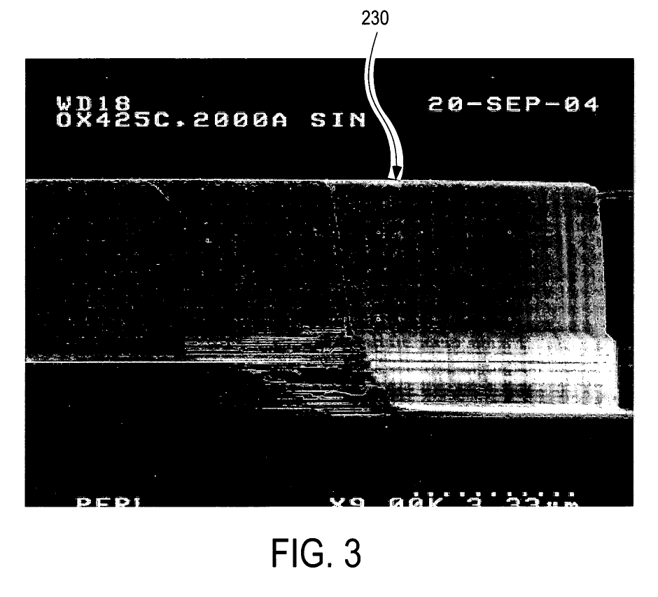

Oxide VCSEL structure 200 is shown in FIG. 2d following the oxidation process. Only Al containing layers whose sidewalls are not covered by conformal dielectric film 205 are oxidized. The darkened shading indicates the oxidized portions and shows oxide defined aperture 277. The oxidized portions include the portions of DBRs 230 with exposed sidewalls as well as current confinement layer 290. FIGS. 1 and 3 show SEM cross-sectional views of oxidation cavity 215 without and with sidewall protection, respectively. The oxide stress in FIG. 3 is seen to be significantly reduced even though oxidation of all DBRs 230 is not eliminated. FIG. 1 shows bending at oxide-semiconductor interface 199 while in FIG. 3 the top of DBRs 230 is flat.

While the invention has been described in conjunction with specific embodiments, it is evident to those skilled in the art that many alternatives, modifications, and variations will be apparent in light of the foregoing description. Accordingly, the invention is intended to embrace all other such alternatives, modifications, and variations that fall within the spirit and scope of the appended claims.

1. A method for a low stress oxide VCSEL structure comprising:
providing a substrate;
forming a plurality of semiconductor layers on said substrate such that a first one of said plurality of semiconductor layers is an active layer comprising an active region and a second one of said plurality of semiconductor layers is a current confinement layer comprising an oxidizable material;
forming a first reflector located on one side of said active layer and forming a second reflector on the opposite side of said active layer;
forming a cavity having sidewalls, said cavity penetrating said first reflector and said second one of said plurality of semiconductor layers.
depositing a conformal dielectric film on said sidewalls.

2. The method of claim 1 wherein said conformal dielectric film comprises Si₃N₄, SiC or SiO₂.

3. The method of claim 1 further comprising a second cavity having sidewalls.

4. The method of claim 1 wherein said cavity is formed by a dry etching process.

5. The method of claim 4 wherein said dry etching process is selected from the group consisting of RIE, ICP-RIE or ECR-RIE.

6. The method of claim 1 further comprising oxidizing said oxidizable material in an oxidation furnace to create an aperture in said current confinement layer.

7. The method of claim 1 wherein said conformal dielectric film is deposited on said sidewalls using PECVD.

8. The method of claim 1 wherein a hard etch stop layer is used to limit the depth of said cavity.

9. The method of claim 8 wherein said hard etch stop layer comprises In.

10. The method of claim 1 wherein said oxidizable material is aluminum.

11. A low stress oxide VCSEL structure comprising:
a substrate;
a plurality of semiconductor layers formed on said substrate;
one of said semiconductor layers comprising an active layer comprising an active region;
a first reflector located on one side of said active layer and a second reflector located on the opposite side of said active layer; and
one of said plurality of semiconductor layers being a current confinement layer, said current confinement layer being penetrated by a plurality of cavities having sidewalls, said sidewalls being coated with a conformal dielectric film.

12. The structure of claim 11 wherein said conformal dielectric film comprises Si₃N₄, SiC or SiO₂.

13. The structure of claim 11 wherein said current confinement layer is an oxidation layer.

14. The structure of claim 13 wherein an unoxidized portion of said current confinement layer defines an aperture.

15. The structure of claim 11 wherein said conformal dielectric film is deposited on said sidewalls using PECVD.

16. The structure of claim 13 wherein said oxidation layer comprises aluminum.

17. The structure of claim 11 wherein said plurality of semiconductor layers comprises a Group III-V arsenide material.

18. The structure of claim 11 wherein said active layer is penetrated by said plurality of cavities.

19. The structure of claim 11 wherein said plurality of cavities are trenches.

20. The structure of claim 11 said second reflector comprises In.
